(19) United States
(12) Patent Application Publication
(10) Pub. No.: US 2021/0249623 A1
(43) Pub. Date: Aug. 12, 2021

(54) DISPLAY DEVICE

(71) Applicant: DENSO TEN Limited, Kobe-shi (JP)

(72) Inventors: Atsushi YAMAWAKI, Kobe-shi (JP); Takeshi MORITA, Kobe-shi (JP)

(73) Assignee: DENSO TEN Limited, Kobe-shi (JP)

(21) Appl. No.: 17/148,679

(22) Filed: Jan. 14, 2021

(30) Foreign Application Priority Data
Feb. 10, 2020 (JP) 2020-020551

(51) Int. Cl. H01L 51/52

(52) U.S. Cl. CPC H01L 51/529

(57) ABSTRACT

A display device includes: a light emitting panel having a light emitting surface; a cover panel configured to cover the light emitting surface; and a cooling unit that is arranged in a space between the cover panel and the light emitting panel and configured to cool the light emitting panel. The cooling unit includes a frame portion that surrounds an outer periphery of the space, and a coolant configured to be supplied into the space from outside of the space and discharged from the space to the outside of the space.

### CROSS-REFERENCE TO RELATED APPLICATIONS

This application is based on and claims priority under 35 USC 119 from Japanese Patent Application No. 2020-020551 filed on Feb. 10, 2020, the contents of which are incorporated herein by reference.

### TECHNICAL FIELD

The present invention relates to a display device.

### RELATED ART

In recent years, display devices including organic light emitting diodes (OLED) are becoming widespread. Such display devices are configured such that, in order to remove heat generated by a light emitting panel including OLEDs, cooling liquid is circulated around the light emitting panel (see, for example, JP-A-2005-326660).

### SUMMARY OF INVENTION

In related art, the number of components is increased due to the cooling liquid, which may cause an increase in a size of the display device, and thus an improvement is required to reduce the size of the display device.

The present invention has been made in view of the above problem, and an object thereof is to provide a display device capable of removing heat generated at the display device while preventing an increase in a size of the display device.

A display device according to embodiments includes: a light emitting panel having a light emitting surface; a cover panel configured to cover the light emitting surface; and a cooling unit that is arranged in a space between the cover panel and the light emitting panel and configured to cool the light emitting panel, the cooling unit including a frame portion that surrounds an outer periphery of the space, and a coolant configured to be supplied into the space from outside of the space and discharged from the space to the outside of the space. According to the display device according to the embodiments, heat generated at the display device may be removed while the increase in the size of the display device is prevented.

### BRIEF DESCRIPTION OF DRAWINGS

FIG. 1A is an exploded perspective view of a display device according to a first embodiment.

FIG. 1B is a schematic diagram of a path of a coolant according to the first embodiment.

FIG. 1C is a schematic diagram of a cooling unit according to the first embodiment.

FIG. 2A is a schematic diagram of a cooling unit according to a second embodiment.

FIG. 2B illustrates a cross-sectional view of the cooling unit taken along line B-B shown in FIG. 2A.

FIG. 2C shows a manufacturing method of the cooling unit according to the second embodiment.

FIG. 2D shows the manufacturing method of the cooling unit according to the second embodiment.

FIG. 3 is a schematic diagram of a cooling unit according to a third embodiment.

FIG. 4 is a schematic diagram of a cooling unit according to a fourth embodiment.

### DESCRIPTION OF EMBODIMENTS

Hereinafter, embodiments of a display device according to the present invention will be described in detail with reference to the drawings. It should be noted that the present invention is not limited to the embodiments.

### First Embodiment

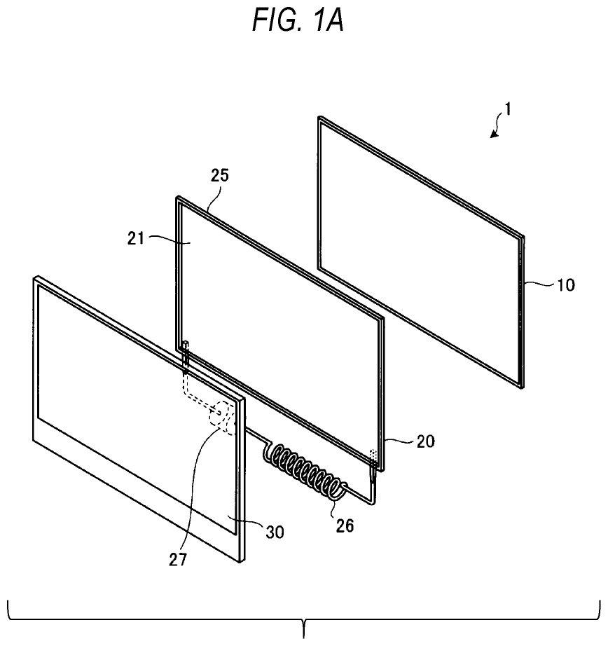

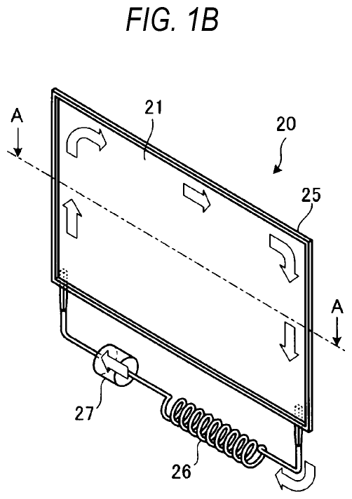

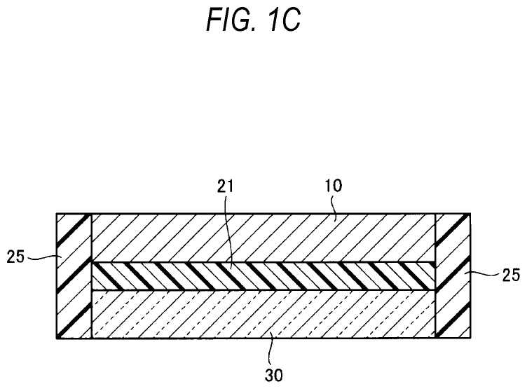

First, a display device according to a first embodiment will be described with reference to FIGS. 1A to 1C. FIG. 1A is an exploded perspective view of the display device according to the first embodiment. FIG. 1B is a schematic diagram of a path of a coolant according to the first embodiment. FIG. 1C is a schematic diagram of a cooling unit according to the first embodiment. Hereinafter, a case where the display device according to the embodiment is a touch panel display installed on an instrument panel of a vehicle will be described.

As shown in FIG. 1A, a display device 1 includes a light emitting panel 10, a cooling unit 20, and a cover panel 30. The light emitting panel 10 is a so-called organic light emitting diode (OLED) panel that includes an OLED, a color filter, and the like (not shown). The light emitting panel 10 may also be a liquid crystal display (LCD) type light emitting panel or a plasma type light emitting panel.

The cooling unit 20 is provided in a space between the light emitting panel 10 and the cover panel 30, and is a layer where a coolant 21 is circulated. The coolant 21 is filler and plays a role of alleviating refractive index changes from the light emitting panel 10 to the cover panel 30. In general, for example, an optical clear adhesive (OCA) or a transparent resin such as an optical clear resin (OCR) is used as the filler.

The cover panel 30 is, for example, a transparent glass plate that covers a main surface of the light emitting panel 10. The cover panel 30 may also be formed of a transparent resin or the like. Since the display device 1 according to the embodiment is a touch panel display, the cover panel 30 also functions as an operation receiving unit that receives a touch operation on the display device 1 of a user. It should be noted that a button or the like may be separately provided on the display device 1, and such a button may be used as the operation receiving unit.

In such a display device, heat generated by the light emitting panel may cause a problem. For example, when a light emitting element is caused to emit light in a state where temperature of the light emitting panel is raised, a service life of the light emitting element may be reduced. When the heat generated by the light emitting panel propagates to the cover panel, temperature of the cover panel may also be increased.

Therefore, in related art, a cooling liquid is circulated around the light emitting panel so as to remove the heat generated at the light emitting panel. However, in this case, it is necessary to separately provide the cooling liquid and a circulation mechanism that circulates the cooling liquid, which is a hindrance to miniaturization of the display device.

Therefore, in the display device 1 according to the embodiment, a bonding layer provided between the light emitting panel 10 and the cover panel 30 is focused on, and a function of cooling the light emitting panel 10 to the bonding layer is imparted thereof. That is, in the display device 1 according to the embodiment, the heat generated by the light emitting panel 10 may be removed while preventing an increase in a size of the display device 1 by further imparting a cooling function to the bonding layer which is a fundamental configuration of the display device 1. In general, the bonding layer is formed of filler that fills a gap between the light emitting panel and the cover panel, an adhesive that bonds the light emitting panel and the cover panel, or the like.

Specifically, as shown in FIG. 1A, the cooling unit 20 includes a cooler 26, a pump 27, and a frame portion 25 that surrounds an outer periphery of the space between the cover panel 30 and the light emitting panel 10. The cooler 26 and the pump 27 correspond to a heat exchange unit. The cooler 26 is, for example, a coil-shaped cylinder, and a cooling mechanism such as a radiator (not shown) is installed outside the cooler 26 so as to cool the coolant 21 passing through inside of the cooler 26.

As shown in FIG. 1B, the cooling unit 20 is filled with the liquid coolant 21. The coolant 21 is cooled by the cooler 26 and then pumped into the cooling unit 20 by the pump 27. As a result, the coolant 21 cooled with the cooler 26 is circulated inside the cooling unit 20.

Here, the coolant 21 is preferably a transparent liquid having a refractive index of about 1.5. As a result, external light entering the display device 1 from the cover panel 30 may be prevented from being reflected at a boundary between the cover panel 30 and the cooling unit 20. In other words, since the refractive index of the coolant 21 is equal to that of the cover panel 30, a decrease in visibility of the display device 1 caused by the external light may be prevented.

In this way, in the display device 1 according to the embodiment, the filler is focused on when the light emitting panel 10 is cooled, and the function of cooling the light emitting panel 10 is imparted to the filler. As a result, in the display device 1 according to the embodiment, the generated heat may be removed while the increase in the size of the display device 1 is prevented.

In the display device 1 according to the embodiment, the heat generated by the light emitting panel 10 is removed by the cooling unit 20 that is abutted against the main surface of the light emitting panel 10, in other words, a heat generating portion of the light emitting panel 10. As a result, in the display device 1 according to the embodiment, the heat generated by the light emitting panel 10 may be efficiently removed.

Such a cooling unit 20 may be configured by the frame portion 25 as shown in FIG. 1C, for example. FIG. 1C corresponds to a cross-sectional view taken along line A-A shown in FIG. 1B.

As shown in FIG. 1C, the frame portion 25 is a frame that surrounds the outer periphery of the space between the light emitting panel 10 and the cover panel 30. The space between the light emitting panel 10 and the cover panel 30 is sealed by the frame portion 25, and the coolant 21 is circulated inside the sealed space.

That is, in this case, since the coolant 21 is circulated over the entire space between the cover panel 30 and the light emitting panel 10, the entire light emitting panel 10 may be uniformly cooled.

### Second Embodiment

However, in the cooling unit 20 according to the first embodiment, the entire light emitting panel 10 may not be uniformly cooled, for example, in a case where a part of the coolant 21 remains inside the cooling unit 20.

Therefore, in the display device 1 according to a second embodiment, the cooling unit 20 includes a guide portion that forms a flow path of the coolant 21. The display device 1 according to the second embodiment differs from the display device 1 according to the first embodiment only in a structure of the cooling unit 20.

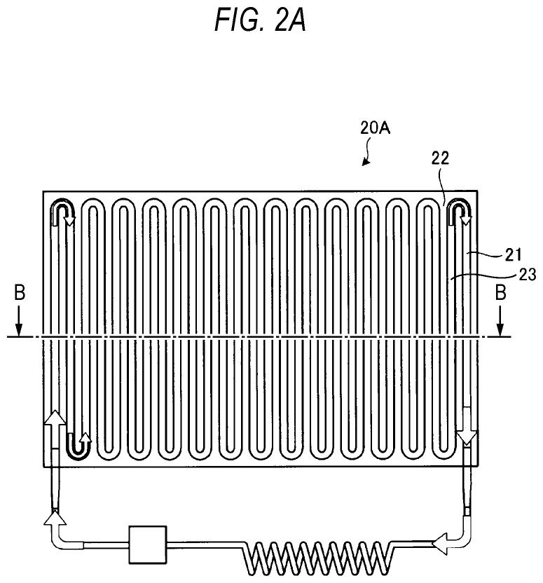

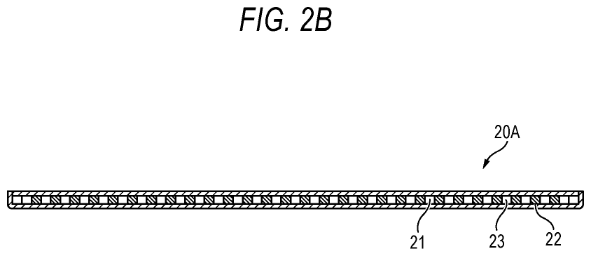

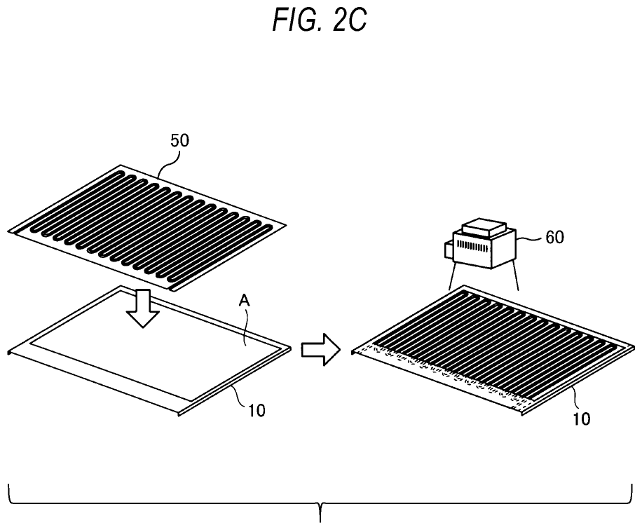

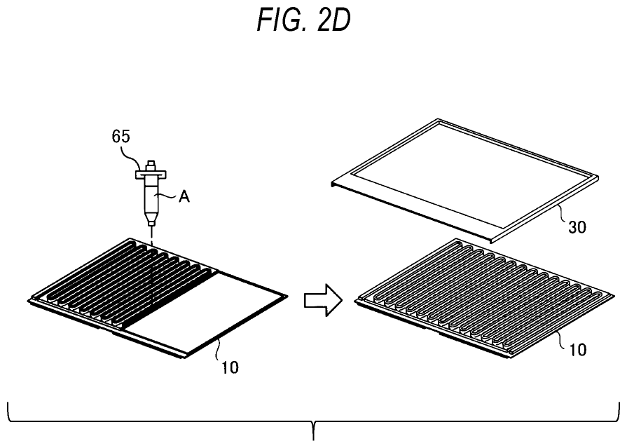

FIG. 2A is a schematic diagram of a cooling unit 20A according to the second embodiment. FIG. 2B illustrates a cross-sectional view of the cooling unit taken along the line B-B shown in FIG. 2A. As shown in FIG. 2A, the cooling unit 20A includes a guide portion 22 that regulates a flow of the coolant 21. In an example shown in FIG. 2A, a case where the flow path 23 of the coolant 21 is formed in a serpentine shape by the guide portion 22 over the entire cooling unit 20A is shown.

Specifically, as shown in FIG. 2A, the flow path 23 is formed by a folded portion that connects a straight linear portion and an adjacent straight linear portion. In this way, by regulating the flow of the coolant 21 by the guide portion 22, circulation efficiency of the coolant 21 may be improved.

Therefore, in the display device 1 according to the second embodiment, the entire light emitting panel 10 may be efficiently cooled. At this time, the guide portion 22 is preferably formed of a resin having substantially the same optical characteristics as those of the coolant 21.

More specifically, the guide portion 22 is a transparent resin, and is preferably a resin (for example, OCR) having a refractive index similar to that of the coolant 21. As a result, the coolant 21 and the guide portion 22 may be prevented from being seen separately when viewed from the side of the cover panel 30. In other words, visibility of images displayed on the display device 1 may be prevented from decreasing.

The flow path 23 of the coolant 21 formed by the guide portion 22 preferably has a substantially constant cross-sectional area as shown in FIG. 2B. As a result, since the flow of the coolant 21 may be kept constant inside the flow path 23, retention of the coolant 21 may be prevented, and the circulation efficiency of the coolant 21 may be improved.

In an example shown in FIG. 2A, the coolant 21 cooled by the cooler 26 flows in one direction. Therefore, it is assumed that the coolant 21 is heated while passing through the flow path 23 in the cooling unit 20A when an amount of the heat generated by the light emitting panel 10 is sufficiently large, and the cooling efficiency changes at a beginning and an end of the flow path 23 of the coolant 21 in the cooling unit 20A.

Therefore, for example, a pumping direction of the coolant 21 pumped by the pump 27 may be reversed at a predetermined cycle. Although a case where one system of flow path 23 is provided is shown in the example of FIG. 2A, the present invention is not limited thereto, and plural systems of flow paths may be provided.

That is, the light emitting panel 10 may be shared and cooled by plural flow paths. In this case, the cooler 26 and the pump 27 may be provided for each of the plural flow paths, or the cooler 26 and the pump 27 may be shared by the plural flow paths.

Such a guide portion 22 may be manufactured by a manufacturing method shown in FIGS. 2C and 2D. FIGS. 2C and 2D illustrate examples of the manufacturing method of the cooling unit 20A according to the second embodiment.

In an example shown in FIG. 2C, a light shielding film 50 printed with a shape of the flow path is laminated on the light emitting panel 10 whose surface is coated with a resin A, then UV is irradiated by a UV irradiator 60 from the side of the light shielding film 50.

As a result, the flow path is left, the resin A is cured, and the uncured resin A that has not been cured is washed away by washing, so that the flow path is formed. In an example shown in FIG. 2D, for example, a dispenser 65 containing the resin A coats the resin A on the surface of the light emitting panel 10 along the guide portion 22.

Thereafter, the cover panel 30 is laminated, from the side of the resin A, on the light emitting panel 10 where the resin A is coated, so that the flow path is formed in a portion where the resin A is not coated. In addition, for example, the flow path may also be formed in the cooling unit 20 by laminating a resin, where the flow path is formed in advance, between the light emitting panel 10 and the cover panel 30.

### Third Embodiment

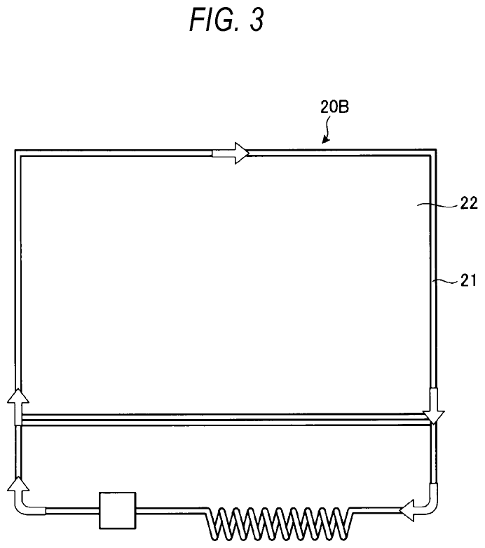

Next, the display device 1 according to a third embodiment will be described with reference to FIG. 3. FIG. 3 is a schematic diagram of a cooling unit 20B according to the third embodiment. In an example shown in FIG. 3, the flow path of the coolant 21 is formed in the cooling unit 20B along an outer periphery of the cooling unit 20B.

More specifically, the flow path of the coolant 21 is formed at a position hidden by an edge of the cover panel 30 or the like. The guide portion 22 fills an inner space of the flow path formed along a peripheral edge portion of the cooling unit 20B. That is, in the example of FIG. 3, the guide portion 22 fills a region excluding the flow path formed along the peripheral edge portion of the cooling unit 20B. Therefore, in this case, since the coolant 21 is hidden by the cover panel 30 or the like, restrictions on the optical characteristics required for the coolant 21 may be relaxed.

That is, in this case, the coolant 21 may not be transparent, and the refractive index thereof may not be considered. Therefore, in this case, for example, a liquid specialized in thermal conductivity or the like may be used.

### Fourth Embodiment

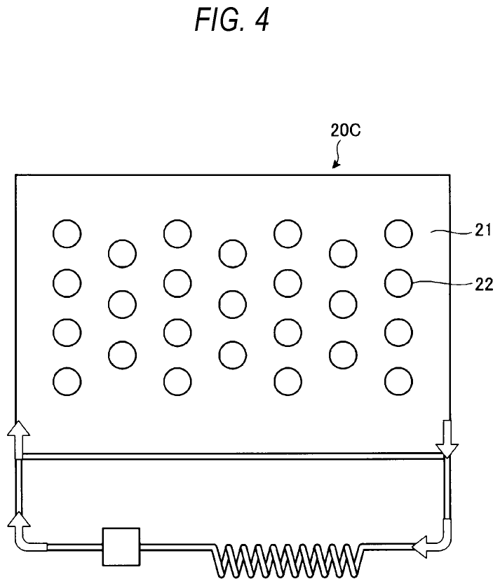

Next, the display device 1 according to a fourth embodiment will be described with reference to FIG. 4. FIG. 4 is a schematic diagram of a cooling unit 20C according to the fourth embodiment. In the second and third embodiments described above, cases where the flow path has a substantially constant cross-sectional area have been described.

In contrast, as shown in FIG. 4, a case where cylindrical guide units 22 are provided in a staggered arrangement in the cooling unit 20C according to the fourth embodiment is shown. In this case, the coolant 21 flows while avoiding the guide portions 22, and the flow of the coolant 21 may be dispersed by the guide portions 22.

The shape and arrangement of the guide portions 22 shown in FIG. 4 are merely examples, and may be appropriately changed such that the coolant 21 flows uniformly in the cooling unit 20 based on fluid engineering, for example.

As described above, the display device 1 according to the embodiment includes the light emitting panel 10, the cover panel 30, and the cooling unit 20. The cover panel 30 covers the light emitting surface of the light emitting panel. The cooling unit 20 is arranged in the space between the cover panel 30 and the light emitting panel 10 to cool the light emitting panel 10. The cooling unit 20 includes the frame portion 25 that surrounds the outer periphery of the space, and the coolant 21 that is supplied into the space from outside the space and is discharged out of the space from the space. Therefore, according to the display device 1 according to the embodiment, the generated heat may be removed while the increase in the size of the display device 1 is prevented.

Although a case where the light emitting panel 10 is cooled by the cooling unit 20 from the side of the cover panel 30 has been described in the embodiment described above, the present invention is not limited thereto. That is, the cooling unit 20 may also be arranged on a back surface side of the light emitting panel 10, and the light emitting panel 10 may be cooled from the back surface side.

Although the display device 1 that cools the light emitting panel 10 by the cooling unit 20 has been described in the embodiment described above, the cooling unit 20 may also be applied to, for example, a lighting device.

Additional effects and modifications can be easily derived by those skilled in the art. Therefore, the broader aspects of the present invention are not limited to the specific details and the representative embodiments shown and described above. Therefore, various modifications may be made without departing from the spirit or scope of the general inventive concept as defined by the appended claims and equivalents thereof

What is claimed is:

1. A display device comprising:
a light emitting panel having a light emitting surface;
a cover panel configured to cover the light emitting surface; and
a cooling unit that is arranged in a space between the cover panel and the light emitting panel and configured to cool the light emitting panel, the cooling unit including
a frame portion that surrounds an outer periphery of the space, and
a coolant configured to be supplied into the space from outside of the space and discharged from the space to the outside of the space.

2. The display device according to claim 1, wherein
the cooling unit includes a heat exchange unit configured to cool the coolant discharged to the outside of the space by heat exchange and supply the coolant into the space.

3. The display device according to claim 1, wherein
the cooling unit includes a guide portion that is provided in the space and forms a flow path of the coolant.

4. The display device according to claim 2, wherein
the cooling unit includes a guide portion that is provided in the space and forms a flow path of the coolant.

5. The display device according to claim 3, wherein
the guide portion forms the flow path having a serpentine shape.

6. The display device according to claim 4, wherein
the guide portion forms the flow path having a serpentine shape.

7. The display device according to claim 3, wherein
the guide portion forms the flow path along a peripheral edge portion of the space, and an inner space of the flow path that is formed along the peripheral edge portion is filled with the coolant.

8. The display device according to claim 4, wherein
the guide portion forms the flow path along a peripheral edge portion of the space, and an inner space of the flow path that is formed along the peripheral edge portion is filled with the coolant.

9. The display device according to claim 3, wherein
the guide portion is formed of a resin having an optical characteristic that is substantially same as an optical characteristic of the coolant.

10. The display device according to claim 4, wherein
the guide portion is formed of a resin having an optical characteristic that is substantially same as an optical characteristic of the coolant.

11. The display device according to claim 5, wherein
the guide portion is formed of a resin having an optical characteristic that is substantially same as an optical characteristic of the coolant.

12. The display device according to claim 6, wherein
the guide portion is formed of a resin having an optical characteristic that is substantially same as an optical characteristic of the coolant.

13. The display device according to claim 7, wherein
the guide portion is formed of a resin having an optical characteristic that is substantially same as an optical characteristic of the coolant.

14. The display device according to claim 8, wherein
the guide portion is formed of a resin having an optical characteristic that is substantially same as an optical characteristic of the coolant.

15. The display device according to claim 3, wherein
the guide portion forms the flow path such that a cross-sectional area of the flow path is substantially constant.
